(19) United States
(12) Patent Application Publication
(10) Pub. No.: US 2020/0075325 A1
(43) Pub. Date: Mar. 5, 2020

(54) FILM FORMING METHOD

(71) Applicant: ASM IP Holding B.V., Almere (NL)

(72) Inventors: Toshiaki IIJIMA, Tokyo (JP); Jun KAWAHARA, Tokyo (JP)

(73) Assignee: ASM IP Holding B.V., Almere (NL)

(21) Appl. No.: 16/116,019

(22) Filed: Aug. 29, 2018

(51) Int. Cl. H01L 21/02

(52) U.S. Cl. CPC H01L 21/02274; H01L 21/02211; H01L 21/0217

(57) ABSTRACT

Examples of a film forming method include placing a substrate on a susceptor arranged in a chamber, and introducing a hydrogen-containing gas and a nitrogen gas into the chamber, and applying radio frequency power to an electrode above the susceptor to generate plasma, and form a nitride film on the substrate, wherein a flow rate of the hydrogen-containing gas is equal to 1% or less of a flow rate of the nitrogen gas.

### TECHNICAL FIELD

Examples are described which relate to a film forming method.

### BACKGROUND

A device structure having a high aspect ratio is required in connection with increase of the density of LSIs. Such a structure is mechanically weak, and may be deformed by the stress of a thin film to be formed later. For a three-dimensional device structure having a high aspect ratio, there is a case where film formation of a SiN film using halogenated silane as a precursor is performed. In this case, in order to enhance a step coating effect of the SiN film, it is considered that the pressure in a chamber is set to a comparatively high pressure of 20 Torr to 30 Torr.

Under the above condition, it is impossible to control the stress of the SiN film. Particularly, when only N₂ is used as a reactant, the compressive stress of the SiN film reaches several hundred megapascals. When a SiN film having a high compressive stress is formed on a substrate having a fine three-dimensional structure, the structure is deformed. Furthermore, when a SiN film having a high compressive stress is formed in a device for improving characteristics by stress control, it causes deterioration of device characteristics.

### SUMMARY

Some examples described herein may address the above-described problems. Some examples described herein may provide a film forming method capable of controlling the stress of a nitride film.

In some examples, a film forming method includes placing a substrate on a susceptor arranged in a chamber, and introducing a hydrogen-containing gas and a nitrogen gas into the chamber, and applying radio frequency power to an electrode above the susceptor to generate plasma, and form a nitride film on the substrate, wherein a flow rate of the hydrogen-containing gas is equal to 1% or less of a flow rate of the nitrogen gas.

### BRIEF DESCRIPTION OF THE DRAWINGS

FIG. 1 is a diagram showing a configuration example of a substrate processing apparatus;

FIG. 2 is a diagram showing an example of a film forming method;

FIG. 3 is a diagram showing the relationship between the flow rate of the H2 gas and the stress of the formed film;

FIG. 4 is a diagram showing the relationship between the flow rate of the H2 gas and the stress of the formed film;

FIG. 5 is a diagram showing the stress of a nitride film formed by a film forming method according to another example; and

FIG. 6 is diagram showing a nitride film.

### DETAILED DESCRIPTION

A film forming method according to an embodiment of the present invention will be described with reference to the drawings. The same or corresponding constituent elements are represented by the same reference signs, and duplicative descriptions thereof may be omitted.

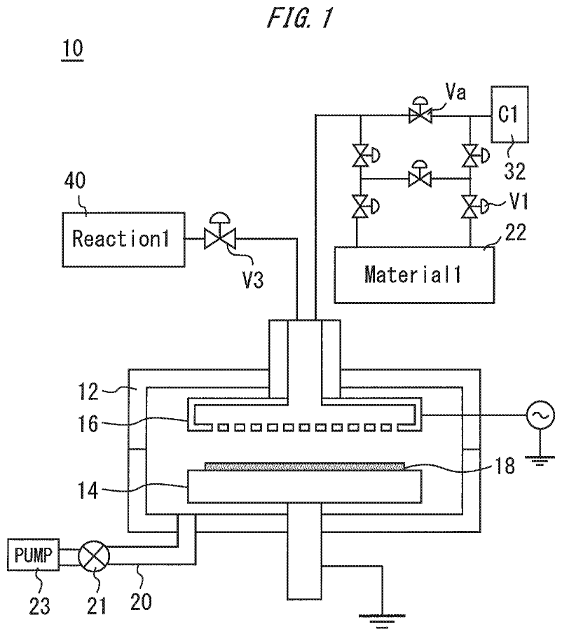

FIG. 1 is a diagram showing a configuration example of a substrate processing apparatus 10. A susceptor 14 is arranged in a chamber 12. A parallel plate structure is provided by the susceptor 14 and an RF electrode 16 arranged on the susceptor 14. Various kinds of gases are provided onto a substrate 18 through openings provided in the RF electrode 16. The susceptor 14 and the RF electrode 16 are provided as a parallel plate, so that capacitively coupled plasma (CCP) can be generated. Plasma processing is applied to the substrate 18 placed on the susceptor 14. The substrate 18 is, for example, a Si wafer. The plasma processing includes film formation processing.

As gas sources, a material gas source 22, a carrier gas source 32, and a reaction gas source 40 are prepared. The material gas source 22 is in a liquid state, and the vapor thereof is provided into the chamber 12 by using a carrier gas from the carrier gas source 32. The carrier gas is, for example, N₂ or Ar. The material gas is, for example, a precursor of the SiN film. That is, the liquid material gas source 22 can be used as a Si precursor for forming the SiN film.

### Si Precursors

In some embodiments, the Si precursor for depositing SiN thin film comprises a silyl halide. In some embodiments, the Si precursor comprises iodine. In certain embodiments, the Si precursor is H₂SiI₂.

Examples of silicon precursors for depositing SiN are provided in U.S. patent application Ser. No. 14/167,904, filed Jan. 29, 2014, entitled “Si PRECURSORS FOR DEPOSITION OF SiN AT LOW TEMPERATURES,” which is incorporated herein by reference in its entirety.

In some embodiments, the Si-precursor comprises iodine and one or more ligands such as one or more organic ligands. In some embodiment, the Si-precursor may comprise iodine and one or more alkyl groups, such as a methyl group, ethyl group, propyl group, and/or hydrogen. In some embodiments, the Si-precursor comprises iodine and one or more other halides, such as bromine or chlorine.

In some embodiments, a silicon precursor comprises three iodines and one amine or alkylamine ligands bonded to silicon. In some embodiments silicon precursor comprises one or more of the following: (SiI₃)NH₂, (SiI₃)NHMe, (SiI₃)NHEt, (SiI₃)NHⁱPr, (SiI₃)NH^{t}Bu, (SiI₃)NMe₂, (SiI₃)NMeEt, (SiI₃)NMeⁱPr, (SiI₃)NMe^{t}Bu, (SiI₃)NEt₂, (SiI₃)NEtⁱPr, (SiI₃)NEt^{t}Bu, (SiI₃)NⁱPr₂, (SiI₃)NⁱPr^{t}Bu, and (SiI₃)N^{t}Bu₂. In some embodiments, a silicon precursor comprises two, three, four, five, six, seven, eight, nine, ten, eleven, twelve, thirteen, fourteen, fifteen or more compounds selected from (SiI₃)NH₂, (SiI₃)NHMe, (SiI₃)NHEt, (SiI₃)NHⁱPr, (SiI₃)NH^{t}Bu, (SiI₃)NMe₂, (SiI₃)NMeEt, (SiI₃)NMeⁱPr, (SiI₃)NMe^{t}Bu, (SiI₃)NEt₂, (SiI₃)NEtⁱPr, (SiI₃)NEt^{t}Bu, (SiI₃)NⁱPr₂, (SiI₃)NⁱPr^{t}Bu, (SiI₃)N^{t}Bu₂, and combinations thereof. In some embodiments, a silicon precursor comprises two iodines and two amine or alkylamine ligands bonded to silicon. In some embodiments, silicon precursor comprises one or more of the following: (SiI₂)(NH₂)₂, (SiI₂)(NHMe)₂, (SiI₂)(NHEt)₂, (SiI₂)(NHⁱPr)₂, (SiI₂)(NH^{t}Bu)₂, (SiI₂)(NNMe₂)₂, (SiI₂)(NMeEt)₂, (SiI₂)(NMeⁱPr)₂, (SiI₂)(NMe^{t}Bu)₂, (SiI₂)(NEt₂)₂, (SiI₂)(NEtⁱPr)₂, (SiI₂)(NEt^{t}Bu)₂, (SiI₂)(NⁱPr₂)₂, (SiI₂)(NⁱPr^{t}Bu)₂, and (SiI₂)(N^{t}Bu)₂. In some embodiments, a silicon precursor comprises two, three, four, five, six, seven, eight, nine, ten, eleven, twelve, thirteen, fourteen, fifteen or more compounds selected from (SiI₂)(NH₂)₂, (SiI₂)(NHMe)₂, (SiI₂)(NHEt)₂, (SiI₂)(NHⁱPr)₂, (SiI₂)(NH^{t}Bu)₂, (SiI₂)(NMe₂)₂, (SiI₂)(NMeEt)₂, (SiI₂)(NMeⁱPr)₂, (SiI₂)(NMe^{t}Bu)₂, (SiI₂)(NEt₂)₂, (SiI₂)(NEtⁱPr)₂, (SiI₂)(NEt^{t}Bu)₂, (SiI₂)(NⁱPr₂)₂, (SiI₂)(NⁱPr^{t}Bu)₂, (SiI₂)(N^{t}Bu)₂, and combinations thereof.

In certain embodiments, a silicon precursor comprises two iodines, hydrogen and one amine or alkylamine ligand or two iodines and two alkylamine ligands bonded to silicon and wherein amine or alkylamine ligands are selected from amine NH₂—, methylamine MeNH—, dimethylamine Me₂N—, ethylmethylamine EtMeN—, ethylamine EtNH—, and diethylamine Et₂N—. In some embodiments silicon precursor comprises one or more of the following: (SiI₂H)NH₂, (SiI₂H)NHMe, (SiI₂H)NHEt, (SiI₂H)NMe₂, (SiI₂H)NMeEt, (SiI₂H)NEt₂, (SiI₂)(NH₂)₂, (SiI₂)(NHMe)₂, (SiI₂)(NHEt)₂, (SiI₂)(NMe₂)₂, (SiI₂)(NMeEt)₂, and (SiI₂)(NEt₂)₂. In some embodiments a silicon precursor comprises two, three, four, five, six, seven, eight, nine, ten, eleven, twelve or more compounds selected from (SiI₂H)NH₂, (SiI₂H)NHMe, (SiI₂H)NHEt, (SiI₂H)NMe₂, (SiI₂H)NMeEt, (SiI₂H)NEt₂, (SiI₂)(NH₂)₂, (SiI₂)(NHMe)₂, (SiI₂)(NHEt)₂, (SiI₂)(NMe₂)₂, (SiI₂)(NMeEt)₂, (SiI₂)(NEt₂)₂, and combinations thereof.

In some embodiments, a silicon precursor comprises one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I8, HSi₂I₅, H₂Si₂I₄, H₃Si₂I₃, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HiMeSi₂I₄, HiMe₂Si₂I₃, HiMe₃Si₂I₂, HiMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I, and H₄EtSi₂I.

In some embodiments, a silicon precursor comprises one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt2MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

In some embodiments, a silicon precursor comprises one iodine, one hydrogen and two amine or alkylamine ligand bonded to silicon. In some embodiments, silicon precursor comprises one or more of the following: (SiIH)(NH₂)₂, (SiIH)(NHMe)₂, (SiIH)(NHEt)₂, (SiIH)(NHiPr)₂, (SiIH)(NHtBu)₂, (SiIH)(NMe₂)₂, (SiIH)(NMeEt)₂, (SiIH)(NMeiPr)₂, (SiIH)(NMetBu)₂, (SiIH)(NEt₂)₂, (SiIH)(NEtiPr)₂, (SiIH)(NEttBu)₂, (SiIH)(NiPr₂)₂, (SiIH)(NiPrtBu)₂, and (SiIH)(NtBu)₂. In some embodiments, a silicon precursor comprises two, three, four, five, six, seven, eight, nine, ten, eleven, twelve, thirteen, fourteen, fifteen or more compounds selected from (SiIH)(NH₂)₂, (SiIH)(NHMe)₂, (SiIH)(NHEt)₂, (SiIH)(NHiPr)₂, (SiIH)(NHtBu)₂, (SiIH)(NMe₂)₂, (SiIH)(NMeEt)₂, (SiIH)(NMeiPr)₂, (SiIH)(NMetBu)₂, (SiIH)(NEt₂)₂, (SiIH)(NEtiPr)₂, (SiIH)(NEttBu)₂, (SiIH)(NiPr₂)₂, (SiIH)(NiPrtBu)₂, and (SiIH)(NtBu)₂, and combinations thereof.

In some embodiments, a silicon precursor comprises one iodine, two hydrogens and one amine or alkylamine ligand bonded to silicon. In some embodiments silicon precursor comprises one or more of the following: (SiIH₂)NH₂, (SiIH₂)NHMe, (SiIH₂)NHEt, (SiIH₃)NHiPr, (SiIH₂)NHtBu, (SiIH₂)NMe₂, (SiIH₂)NMeEt, (SiIH₂)NMeiPr, (SiIH₂)NMetBu, (SiIH₂)NEt₂, (SiIH₂)NEtiPr, (SiIH₂)NEttBu, (SiIH₂)NiPr₂, (SiIH₂)NtPrtBu, and (SiIH₂)NtBu₂. In some embodiments a silicon precursor comprises two, three, four, five, six, seven, eight, nine, ten, eleven, twelve, thirteen, fourteen, fifteen or more compounds selected from (SiIH₂)NH₂, (SiIH₂)NHMe, (SiIH₂)NHEt, (SiIH₂)NHiPr, (SiIH₂)NHtBu, (SiIH₂)NMe₂, (SiIH₂)NMeEt, (SiIH₂)NMeiPr, (SiIH₂)NMetBu, (SiIH₂)NEt₂, (SiIH₂)NEtiPr, (SiIH₂)NEttBu, (SiIH₂)NiPr₂, (SiIH₂)NiPrtBu, (SilH₂)NtBu₂, and combinations thereof.

In some embodiments, a silicon precursor comprises one iodine and three amine or alkylamine ligands bonded to silicon. In some embodiments, silicon precursor comprises one or more of the following: (SiI)(NH₂)₃, (SiI)(NHMe)₃, (SiI)(NHEt)₃, (SiI)(NHiPr)₃, (SiI)(NHtBu)₃, (SiI)(NMe₂)₃, (SiI)(NMeEt)₃, (SiI)(NMeiPr)₃, (SiI)(NMetBu)₃, (SiI)(NEt₂)₃, (SiI)(NEtiPr)₃, (SiI)(NEttBu)₃, (SiI)(NiPr₂)₃, (SiI)(NiPrtBu)₃, and (SiI)(NtBu)₃. In some embodiments a silicon precursor comprises two, three, four, five, six, seven, eight, nine, ten, eleven, twelve, thirteen, fourteen, fifteen or more compounds selected from (SiI) (NH₂)₃, (SiI)(NHMe)₃, (SiI)(NHEt)₃, (SiI)(NHiPr)₃, (SiI)(NHtBu)₃, (SiI)(NMe₂)₃, (SiI)(NMeEt)₃, (SiI)(NMeiPr)₃, (SiI)(NMetBu)₃, (SiI)(NEt₂)₃, (SiI)(NEtiPr)₃, (SiI)(NettBu)₃, (SiI)(NiPr₂)₃, (SiI)(NiPrtBu)₃, (SiI)(NtBu)₃, and combinations thereof. In certain embodiments, a silicon precursor comprises two iodines, hydrogen and one amine or alkylamine ligand or two iodines and two alkylamine ligands bonded to silicon and wherein amine or alkylamine ligands are selected from amine NH₂—, methylamine MeNH—, dimethylamine ethylmethylamine EtMeN—, ethylamine EtNH—, and diethylamine Et₂N—. In some embodiments silicon precursor comprises one or more of the following: (SiI₂H)NH₂, (SiI₂H)NHMe, (SiI₂H)NHEt, (SiI₂H)NMe₂, (SiI₂H)NMeEt, (SiI₂H)NEt₂, (SiI₂)(NH₂)₂, (SiI₂)(NHMe)₂, (SiI₂)(NHEt)₂, (SiI₂)(NMe₂)₂, (SiI₂)(NMeEt)₂, and (SiI2)(NEt₂)₂. In some embodiments a silicon precursor comprises two, three, four, five, six, seven, eight, nine, ten, eleven, twelve or more compounds selected from (SiI₂H)NH₂, (SiI₂H)NHMe, (SiI₂H)NHEt, (SiI₂H)NMe₂, (SiI₂H)NMeEt, (SiI₂H)NEt₂, (SiI₂)(NH₂)₂, (SiI₂)(NHMe)₂, (SiI₂)(NHEt)₂, (SiI₂)(NIVIe₂)₂, (SiI₂)(NMeEt)₂, (SiI₂)(NEt₂)₂, and combinations thereof.

The material of a hydrogen-containing gas can be stored as the Si precursor in the material gas source 22. Any material of the above-described Si precursors may be used as the hydrogen-containing gas, but halogenated silane such as H₂SiI₂ may be used, for example. For example, an Nitrogen precursor such as N₂ is stored in the reaction gas source 40.

### N Precursors

As discussed above, the second reactant for depositing silicon nitride according to the present disclosure may comprise a nitrogen precursor, which may comprise a reactive species. Suitable plasma compositions of a PEALD process include nitrogen plasma, radicals of nitrogen, or atomic nitrogen in one form or another. In some embodiments, hydrogen plasma, radicals of hydrogen, or atomic hydrogen in one form or another are also provided. And in some embodiments, a plasma may also contain noble gases, such as He, Ne, Ar, Kr and Xe, preferably Ar or He, in plasma form, as radicals, or in atomic form. In some embodiments, the second reactant does not comprise any species from a noble gas, such as Ar. Thus, in some embodiments plasma is not generated in a gas comprising a noble gas.

Whether or not gas is supplied from the material gas source 22, the carrier gas source 32, and the reaction gas source 40 and also the gas flow rates thereof are adjusted by valves V1, Va, and V3, respectively. An exhaust pipe 20 is connected to the chamber 12. A valve 21 and a pump 23 are fitted to the exhaust pipe 20. For example, the pressure in the chamber 12 can be determined by adjusting the opening degree of the valve 21 and the pumping ability of the pump 23.

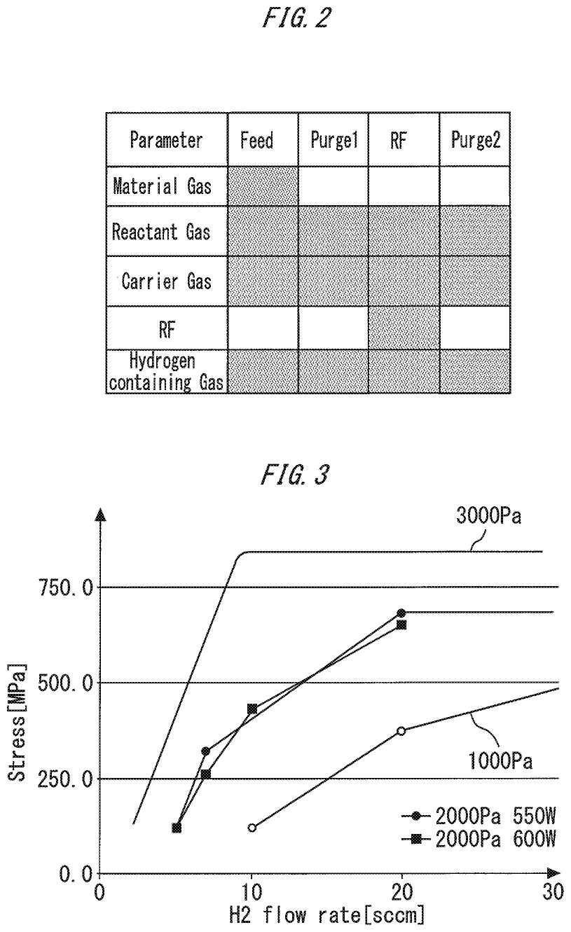

FIG. 2 is a diagram showing an example of a film forming method. In this film forming method, the nitride film is formed on the substrate by a PEALD method. Specifically, Feed, Purge 1, RF, and Purge 2 are repeated at plural times in this order.

In the step of Feed, after the substrate 18 is placed on the susceptor 14, a precursor, for example, as a Si precursor, is provided in the chamber 12. Specifically, the vapor of the material gas source 22 may be provided into the chamber 12 together with the gas of the carrier gas source 32. As a result, the Si precursor is provided onto the substrate 18. In all the steps of Feed, Purge 1, RIF, and Purge 2, the reactant gas from the reaction gas source 40 may be provided into the chamber 12, and the carrier gas from the carrier gas source 32 may be provided into the chamber 12.

In the step of Purge 1, purge is performed to exhaust unnecessary materials. In this step, for example, a surplus Si precursor is exhausted.

In the step of RF, radio frequency power (RF power) is applied to the RF electrode 16 to generate plasma and form the SiN film on the substrate 18. Plasma may include N radicals, H radicals, NH radicals, and NH₂ radicals. The time for which the radio frequency power is applied to the RF electrode 16 is set to, for example, 3.3 seconds.

In the step of Purge 2, purge is performed to exhaust unnecessary materials. In a series of processing, nitrogen gas as the reaction gas can be made to flow continuously. By repeating this series of processing at plural times, the SiN film is formed on the substrate 18. The film thickness of the SiN film is set to, for example, 2 nm or less. In order to form the SiN film of about 2 nm, the above series of processing is performed, for example, at about 100 to 200 cycles.

As shown at the bottom stage of FIG. 2, a hydrogen-containing gas is always supplied into the chamber during formation of the nitride film. In this example, the material gas from the material gas source 22 is provided in all the steps of Feed, Purge 1, RF, and Purge 2, thereby providing the hydrogen-containing gas. That is, in this example, the hydrogen-containing gas is the vapor of the material gas source 22. In the step of Feed, the supply amount of the gas from the material gas source 22 can be increased, and in subsequent steps thereto, the supply amount of the gas can be reduced. The hydrogen-containing gas is supplied to control the stress of the nitride film.

Various kinds of gases containing hydrogen can be adopted as the hydrogen-containing gas. For example, DCS (dichlorosilane), ammonia, H₂, CHₓ, BHₓ or the like can be used as the hydrogen-containing gas. In case where the hydrogen-containing gas differs from the material gas, the hydrogen-containing gas is supplied into the chamber from a system different from that of the material gas source 22.

For example, there is considered a case where the internal pressure of the chamber 12 is set to 2000 Pa, the HRF power to be applied to the RF electrode 16 is set to 660 W, the distance between the electrodes of the parallel plate is set to 12 mm, and the step of RF is performed without introducing any hydrogen-containing gas. That is, in the step of RF, the reactant gas and the carrier gas are provided into the chamber. In this case, the compressive stress of the nitride film reaches several hundred megapascals. On the other hand, when hydrogen-containing gas such as H₂ gas is introduced in the step of RF under the same film forming condition, a tensile stress can be generated in the nitride film. This is considered to be because H atoms which are temporarily captured into a thin film during film formation are desorbed, so that the thin film tries to shrink.

FIG. 3 is a diagram showing the relationship between the flow rate of the H₂ gas to be introduced into the chamber in the step of RF and the stress of the fanned nitride film. H₂ gas corresponds to the hydrogen-containing gas. FIG. 3 shows data when the pressure in the chamber is set to 1000 Pa, 2000 Pa, 3000 Pa, When the pressure in the chamber is set to 2000 Pa, the HRF power is set to 550 W or 600 W and the flow rate of the hydrogen-containing gas is changed within the range from 5 to 20 sccm, the nitride film becomes a film having a tensile stress of 125 to 680 MPa. The reason why the tensile stress of the nitride film increases as the amount of hydrogen-containing gas is increased is considered to be that the amount of H atoms captured into the film increases as the amount of hydrogen-containing gas is increased, and the shrinking amount of the film increases accordingly. In this example, by changing the flow rate of the hydrogen-containing gas from 0 sccm to 20 sccm, the stress of the nitride film can be changed. When the flow rate of the hydrogen-containing gas is equal to 0 sccm, the proportion occupied by the hydrogen-containing gas among the gases supplied into the chamber is equal to 0%. When the flow rate of the hydrogen-containing gas is equal to 20 sccm, the proportion occupied by the hydrogen-containing gas among the gases supplied into the chamber is equal to, for example, 0.14%.

When the flow rate of the hydrogen-containing gas is set to 20 sccm or more, the stress of the nitride film becomes constant, and even when the flow rate is further increased, the stress hardly changes. This is considered to be because the stress control effect caused by the H atoms captured in the film is saturated when the supply amount of the hydrogen-containing gas exceeds a certain flow rate.

The flow rate of the hydrogen-containing gas at which the saturation of the stress control effect appears depends on the pressure in the chamber. For example, FIG. 3 shows that under the pressure of 1000 Pa in the chamber, the stress of the film increases even when the supply amount of the hydrogen-containing gas is increased beyond 20 sccm. On the other hand, under the pressure of 3000 Pa in the chamber, it is possible to control the stress of the film by adjusting the flow rate of the hydrogen-containing gas in the range from about 0 to 10 sccm, but when the flow rate of the hydrogen-containing gas exceeds 10 sccm, the stress does not change even by further increasing the flow amount of the hydrogen-containing gas.

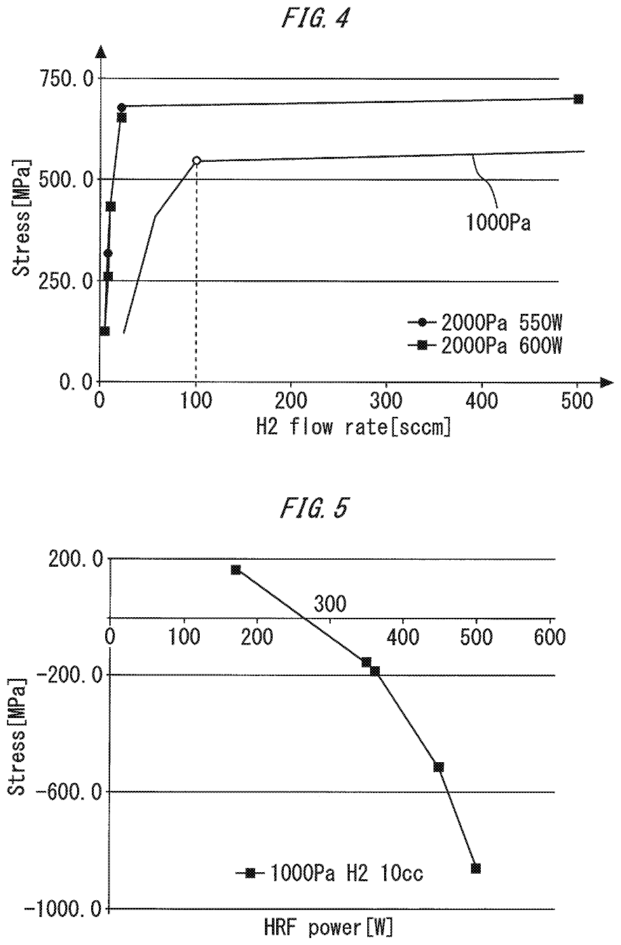

FIG. 4 is a graph showing the relationship between the flow rate of the H₂ gas to be introduced into the chamber in the step of RF and the stress of the formed nitride film. FIG. 4 shows the stress when the flow rate of the hydrogen-containing gas is changed in the range from 0 to 500 sccm. Under the pressure of 1000 Pa in the chamber, when the flow rate of the hydrogen-containing gas is equal to 10 sccm or less, it is possible to adjust the stress of the nitride film by adjusting the flow rate of the hydrogen-containing gas. On the other hand, when the flow rate of the hydrogen-containing gas exceeds 100 sccm, the stress adjustment effect of the nitride film by the adjustment of the flow rate of the hydrogen-containing gas is saturated.

As described above, the tensile stress of the SiN film can be controlled by changing the flow rate of the hydrogen-containing gas. When the pressure in the chamber is set to, for example, 2000 Pa or more, the coating effect of the substrate by the nitride film can be enhanced.

FIG. 5 is a diagram showing the stress of a nitride film formed by a film forming method according to another example. In this example, 0.07% of the total flow rate is set to be occupied by H₂ gas which is the hydrogen-containing gas. In this example, it is shown that the stress of the nitride film can be made a compressive stress by adjusting the RF power to be applied to the RF electrode. When the nitride film has a compressive stress, the value of the stress in FIG. 5 is a negative value. For example, a compressive stress is generated in the nitride film by introducing 10 cc of H₂ gas as the hydrogen-containig gas, setting the pressure in the chamber to 1000 Pa, and adjusting the HRF power. The compressive stress can be generated by applying electric power of 350 W or more. When the RF power is changed from 350 W to 500 W, the stress of the nitride film changes from −158.1 MPa to −864.8 MPa. From this result, it is apparent that the compressive stress of the SiN film can be controlled by changing the HRF power under a condition that a small amount of H₂ is added.

From the results described above, it is possible to generate a compressive stress, for example, by using halogenated silane which is the film forming material as the hydrogen-containing gas and setting the pressure in the chamber to 1000 Pa during film formation, and a tensile stress can be generated by making the pressure in the chamber ranging from more than 1000 Pa to not more than 2000 Pa.

In the step of RF in FIG. 2, H₂ can be supplied as the hydrogen-containing gas in addition to N₂ as the reactant gas. At this time, the flow rate of H₂ may be set to 1% or less of the flow rate of N₂. The stress control can be performed by introducing the hydrogen-containing gas and the nitrogen gas into the chamber and applying radio frequency power to the RF electrode 16 on the susceptor 14 to generate plasma and form the nitride film on the substrate 18. In particular, the flow rate of the hydrogen-containing gas is set to 1% or less of the flow rate of the nitrogen gas, thereby enhancing stress controllability. For example, FIG. 3 shows that when the flow rate of the hydrogen-containing gas is small, it is easier to control the stress of the nitride film by adjusting the flow rate of the hydrogen-containing gas. As described above, it is possible to generate the compressive stress as well as the tensile stress in the nitride film to be formed.

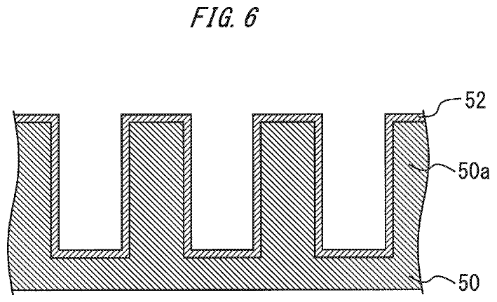

FIG. 6 is a diagram showing a nitride film formed while providing a hydrogen-containing gas. A convex portion 50a is formed on a substrate 50, so that there is an uneven pattern on the surface of the substrate. This uneven pattern is covered with a nitride film 52. When the surface of the substrate 50 has an uneven pattern and the uneven pattern is covered with the nitride film, it is desired to prevent the substrate 50 from being deformed by the stress of the nitride film 52, For example, by reducing the stress of the nitride film according to the foregoing method, deformation of the substrate 50 can be suppressed. Further, in each of the foregoing examples, formation of the nitride film with the pressure in the chamber set to 1000 Pa or more contributes to the enhancement of the coating effect by the nitride film.

1. A film forming method comprising:
placing a substrate on a susceptor arranged in a chamber; and
as a part of the a PEALD method, introducing a hydrogen-containing gas and a nitrogen gas into the chamber, and applying radio frequency power to an electrode above the susceptor to generate plasma, and form a nitride film on the substrate, wherein a flow rate of the hydrogen-containing gas is equal to 1% or less of a flow rate of the nitrogen gas.

2. The film forming method according to claim 1, wherein the nitride film is formed with a pressure in the chamber set to 1000 Pa or more.

3. The film forming method according to claim 1, wherein the PEALD method repeat feeding a material gas into the chamber, first purging, the nitride film formation, and second purging in this order.

4. The film forming method according to claim 3, wherein the nitrogen gas is made to flow continuously.

5. The film forming method according to claim 1, wherein the hydrogen-containing gas is halogenated silane.

6. The film forming method according to claim 1, wherein the plasma is capacitively coupled plasma.

7. The film forming method according to claim 1, wherein the nitride film is made as a film having a compressive stress.

8. The film forming method according to claim 1, wherein the nitride film is made as a film having a tensile stress.

9. The film forming method according to claim 1, wherein a surface of the substrate has an uneven pattern, and the nitride film covers the uneven pattern.

10. The film forming method according to claim 3, wherein in the nitride film formation, the material gas is introduced into the chamber as the hydrogen-containing gas.

11. The film forming method according to claim 10, wherein the material gas is introduced into the chamber throughout the PEALD method.

12. The film forming method according to claim 11, wherein the supply amount of the material gas in the feeding is larger than the supply amount of the material gas in the first purging, the nitride film formation, and the second purging.

13. The film forming method according to claim 3, wherein the hydrogen-containing gas is different from the material gas.
